(19) United States
(12) Patent Application Publication
(10) Pub. No.: US 2025/0239477 A1
(43) Pub. Date: Jul. 24, 2025

(54) LIGHT-EMITTING ELEMENT ARRAY SUBSTRATE AND METHOD FOR MANUFACTURING LIGHT-EMITTING ELEMENT ARRAY SUBSTRATE

(71) Applicant: AUO Corporation, Hsinchu (TW)

(72) Inventors: Kuan-Yi Lee, Hsinchu (TW); Wei-Chieh Chen, Hsinchu (TW); Chien-Hung Kuo, Hsinchu (TW)

(73) Assignee: AUO Corporation, Hsinchu (TW)

(21) Appl. No.: 18/770,679

(22) Filed: Jul. 12, 2024

(30) Foreign Application Priority Data
Jan. 23, 2024 (TW) 113102529

(51) Int. Cl. H01L 21/683; H01L 25/075; H01L 33/62

(52) U.S. Cl. CPC H01L 21/6835; H01L 25/0753; H10H 20/857; H01L 2221/68354; H01L 2221/68368; H10H 20/0364

(57) ABSTRACT

A light-emitting element array substrate includes a temporary base, an adhesive layer, light-emitting elements and at least one support member. The temporary storage base has a first surface and a second surface opposite to each other. The adhesive layer is disposed on the first surface of the temporary storage base. The light-emitting elements are disposed on the adhesive layer. The adhesive layer is located between the light-emitting elements and the temporary storage substrate. The at least one support member is disposed on at least one of the first surface and the second surface of the temporary storage base. In addition, a method for manufacturing a light-emitting element array substrate is also provided.

### CROSS-REFERENCE TO RELATED APPLICATION

This application claims the priority benefit of Taiwan application serial no. 113102529, filed on Jan. 23, 2024. The entirety of the above-mentioned patent application is hereby incorporated by reference herein and made a part of this specification.

### BACKGROUND

### Technical Field

The disclosure relates to an array substrate and a manufacturing method of the array substrate, and in particular, to a light-emitting element array substrate and a manufacturing method of the light-emitting element array substrate.

### Description of Related Art

A light-emitting diode display panel includes a driving backplane and a plurality of light-emitting diode elements transferred onto the driving backplane. Inheriting the characteristics of light-emitting diodes, the light-emitting diode display panel has advantages of power saving, high efficiency, high brightness, and fast response time. In addition, compared with an organic light-emitting diode display panel, the light-emitting diode display panel further has advantages of easy color adjustment, long light emission life, no image burn-in, etc. Therefore, the light-emitting diode display panel is considered as a display technology of the next generation.

During the manufacturing process of a light-emitting diode display panel, light-emitting diode elements must be transferred multiple times in order to connect the light-emitting diode elements to the driving backplane. However, as the number of transpositions increases, the overall offset of the light-emitting diode elements continues to accumulate, resulting in a decrease in the bonding yield of the light-emitting diode elements and the driving backplane. In addition, during the transposition process, bonding mura is prone to occur on the temporary substrate used to temporarily store light-emitting diode elements, which may lead to abnormal debonding of the light-emitting diode elements.

### SUMMARY

This disclosure provides a light-emitting element array substrate with an adhesive layer that has good film thickness uniformity.

This disclosure provides a method for manufacturing a light-emitting element array substrate, which can produce a light-emitting element array substrate with good film thickness uniformity of an adhesive layer.

The light-emitting element array substrate in one embodiment of this disclosure includes a temporary base, an adhesive layer, light-emitting elements and at least one support member. The temporary base has a first surface and a second surface opposites to each other. An adhesive layer is disposed on a first surface of the temporary base. The light-emitting elements are disposed on the adhesive layer. The adhesive layer is located between the light-emitting elements and the temporary base. The at least one support member is disposed on at least one of the first surface and the second surface of the temporary base.

The manufacturing method of a light-emitting element array substrate according to an embodiment of this disclosure includes the following steps: providing a light-emitting elements supply substrate, wherein the light-emitting elements supply substrate comprises a temporary base and light-emitting elements, the temporary base of the light-emitting elements supply substrate has a first surface and a second surface opposites to each other, and the light-emitting elements are disposed on the first surface of the temporary base of the light-emitting elements supply substrate; providing a temporary substrate, wherein the temporary substrate comprises a temporary base and an adhesive layer disposed on the temporary base; making the first surface of the temporary base of the light-emitting elements supply substrate face the adhesive layer, so that the light-emitting elements are disposed between the temporary base of the light-emitting elements supply substrate and the adhesive layer of the temporary substrate; using a pressure head to press down the second surface of the temporary base of the light-emitting elements supply substrate, so that the light-emitting elements are connected to the adhesive layer of the temporary substrate, wherein a support member is provided between the pressure head and the second surface of the temporary base of the light-emitting elements supply substrate, and the pressure head presses against the second surface of the temporary base of the light-emitting elements supply substrate through the support member; and separating the temporary base of the light-emitting elements supply substrate and the light-emitting elements so that the light-emitting elements are transferred to the adhesive layer of the temporary substrate.

### BRIEF DESCRIPTION OF THE DRAWINGS

FIG. 1A to FIG. 1H are schematic cross-sectional views of the manufacturing process of a display device according to an embodiment of this disclosure.

FIG. 2A to FIG. 2B are schematic cross-sectional views of a part of the manufacturing process of a display device according to another embodiment of the present disclosure.

FIG. 3 is a schematic cross-sectional view of a light-emitting element array substrate according to another embodiment of the present disclosure.

FIG. 4 is a schematic top view of a light-emitting element array substrate according to another embodiment of the present disclosure.

FIG. 5A to FIG. 5B are schematic cross-sectional views of a part of the manufacturing process of a display device according to another embodiment of the present disclosure.

FIG. 6 is a top view and a perspective view of a temporary base, an adhesive layer and a support member of another embodiment of the disclosure.

FIG. 7 is a top view and a perspective view of an adhesive layer, a temporary base, a first support member and a second support member of a light-emitting element array substrate according to yet another embodiment of the present disclosure.

FIG. 8 is a top view and a perspective view of a temporary base, an adhesive layer and a first support member of a light-emitting element array substrate according to an embodiment of this disclosure.

FIG. 9 is a partially enlarged schematic diagram of the first support member of an embodiment of the disclosure.

FIG. 10 is a top view and a perspective view of a temporary base, an adhesive layer and a first support member of a light-emitting element array substrate according to another embodiment of this disclosure.

FIG. 11 is a partially enlarged schematic diagram of the first support member of another embodiment of the disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

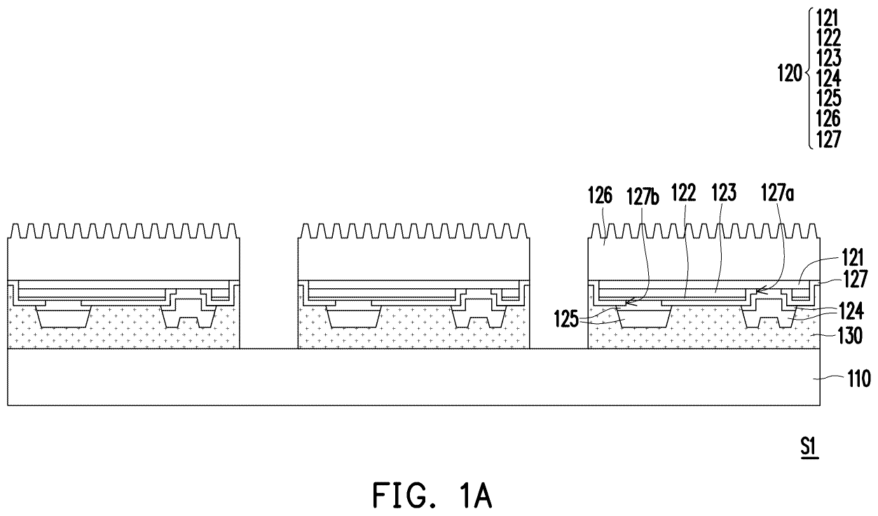

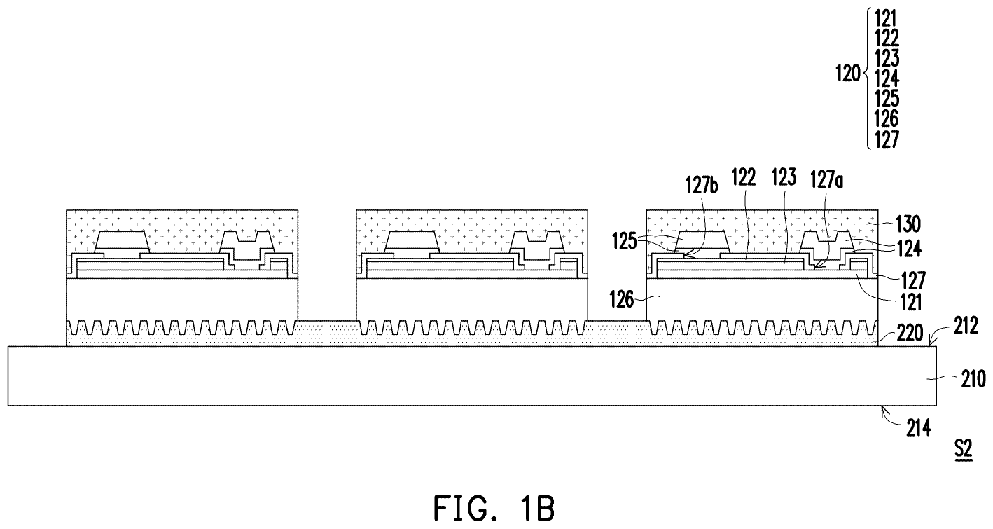

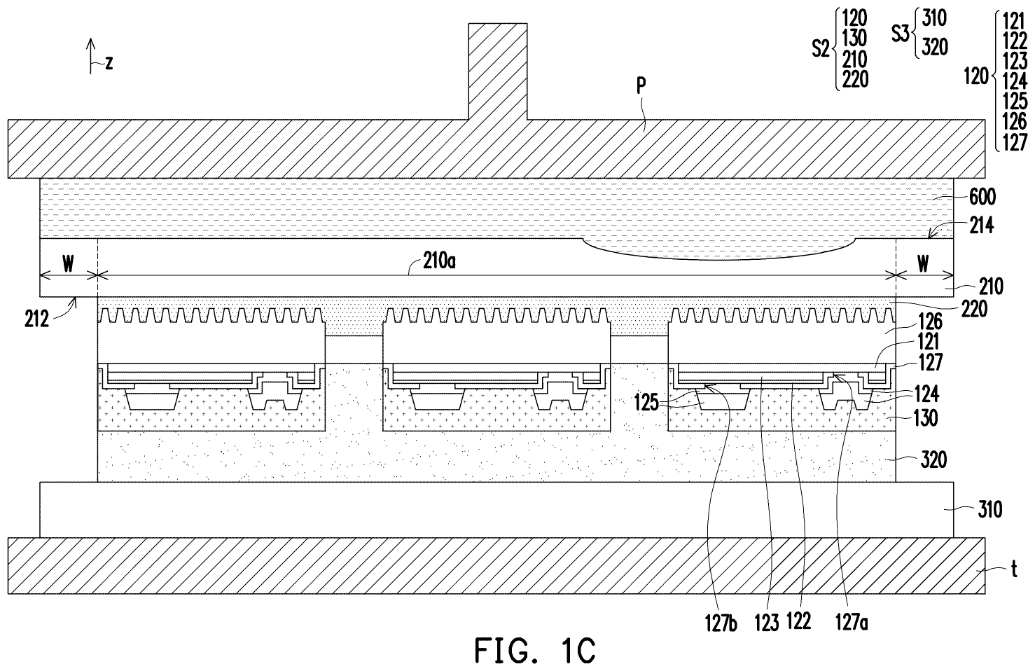

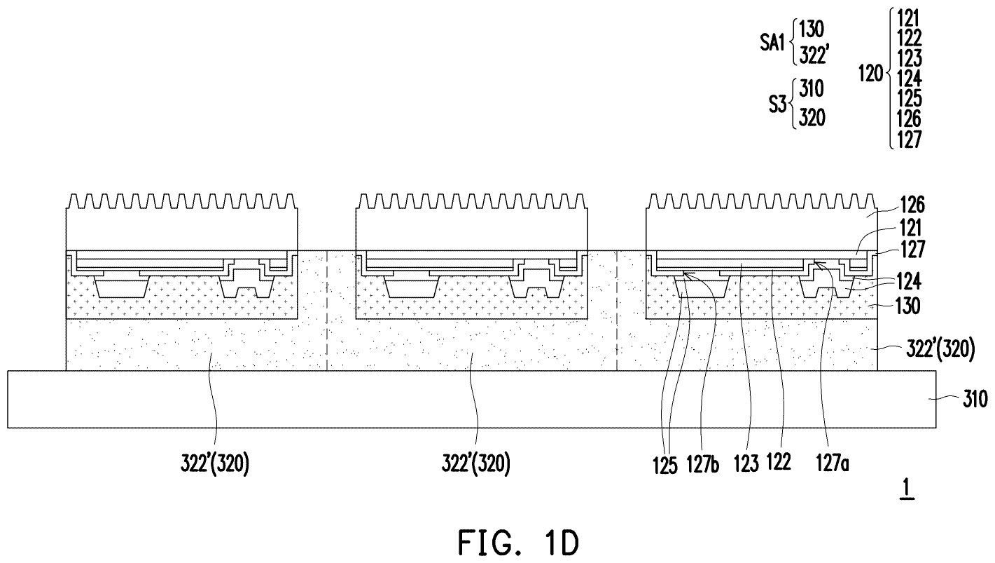

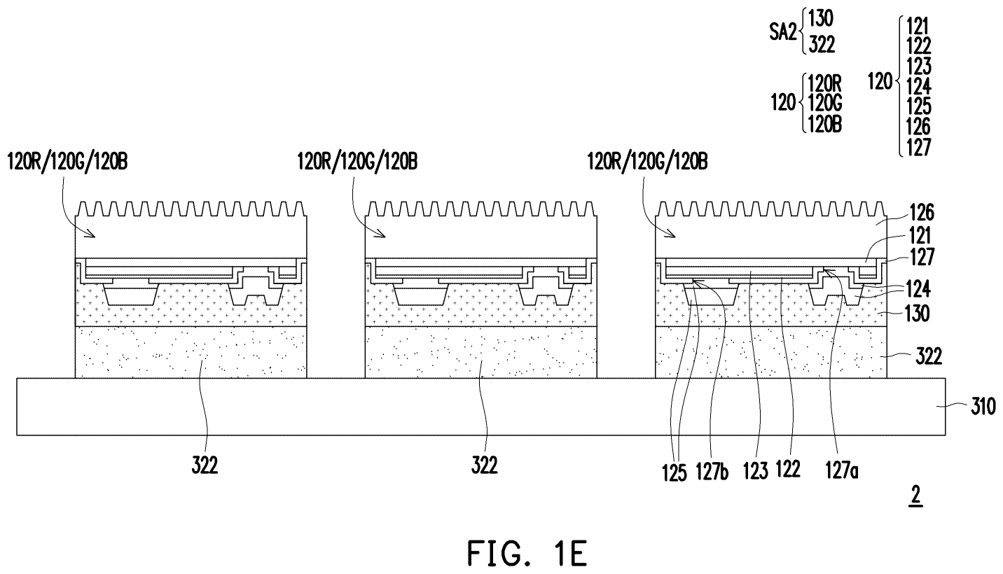

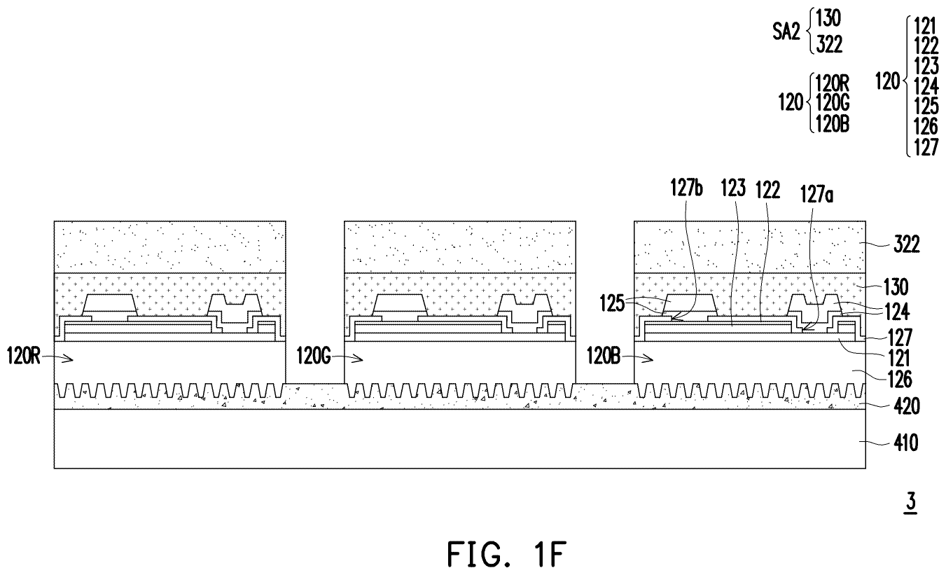

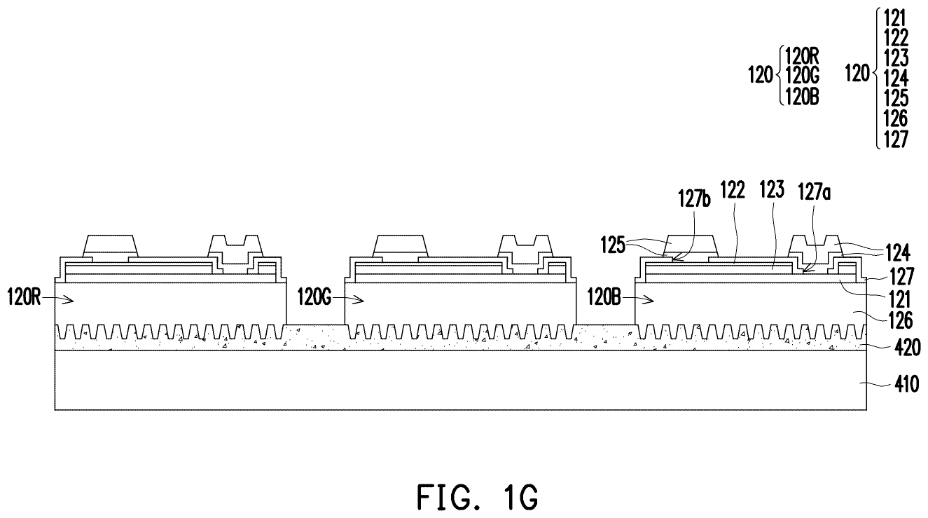

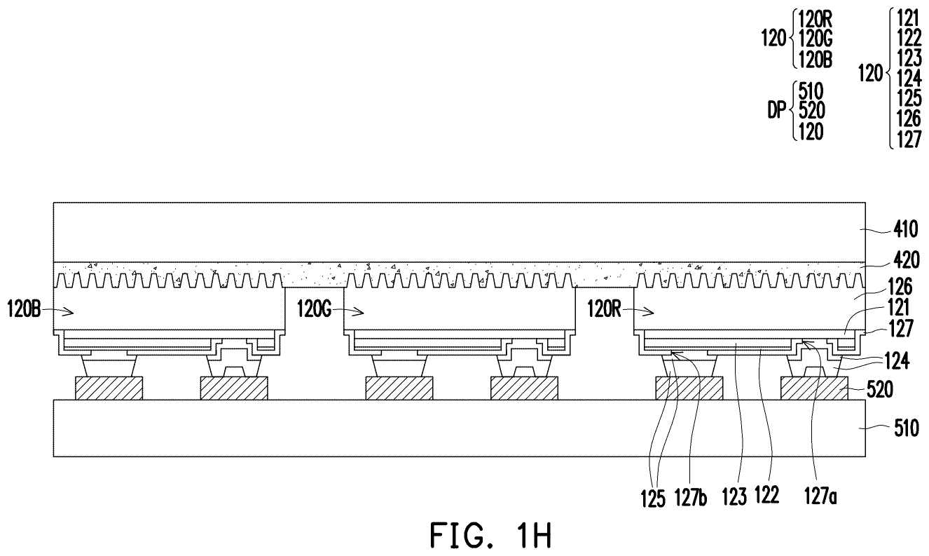

FIG. 1A to FIG. 1H are schematic cross-sectional views of the manufacturing process of a display device according to an embodiment of this disclosure. Please refer to FIG. 1A, first, a light-emitting elements supply substrate S1 is provided. FIG. 1A shows a light-emitting elements supply substrate S1 as a representative. Each of the light-emitting elements supply substrate S1 includes a temporary base 110 and light-emitting elements 120 disposed on the temporary base 110. In one embodiment, the light-emitting elements supply substrate S1 may optionally further include first adhesive members 130. The first adhesive members 130 are disposed between the light-emitting elements 120 and the temporary base 110. The first adhesive members 130 are disposed on the temporary base 110 and separated from each other, and the light-emitting elements 120 are respectively disposed on the first adhesive members 130.

In one embodiment, each of the light-emitting elements 120 includes a first semiconductor layer 121, a second semiconductor layer 122, an active layer 123 disposed between the first semiconductor layer 121 and the second semiconductor layer 122, and the electrodes 124, 125 electrically connected to the first semiconductor layer 121 and the second semiconductor layer 122, respectively. In one embodiment, the light-emitting elements 120 are, for example, micro light-emitting diodes (μLEDs).

In one embodiment, each of the light-emitting elements 120 may also optionally include an epitaxial layer 126, the first semiconductor layer 121 is formed on the epitaxial layer 126, and the first semiconductor layer 121 is located between the epitaxial layer 126 and the active layer 123. For example, in one embodiment, the epitaxial layer 126 may be undoped gallium nitride, the first semiconductor layer 121 may be n-type gallium nitride, the active layer 123 may be a multiple quantum well layer, and the second semiconductor layer 123 may be p-type gallium nitride, but this disclosure is not limited to thereto.

In one embodiment, each of the light-emitting elements 120 may also optionally include an insulating layer 127, the insulating layer 127 is disposed on the second semiconductor layer 122 and has contact windows 127a and 127b respectively overlapping the first semiconductor layer 121 and the second semiconductor layer 122, and the electrodes 124 and 125 are electrically connected to the first semiconductor layer 121 and the second semiconductor layer 122 respectively through the contact windows 127a and 127b of the insulating layer 127.

Please refer to FIG. 1A and FIG. 1B, next, a temporary base 210 and an adhesive layer 220 disposed on the temporary base 210 are provided, wherein an area of the temporary base 210 is larger than an area of the temporary base 110. A shape of the temporary base 210 and a shape of the temporary base 110 may be different. For example, in one embodiment, the temporary base 110 is, for example, a 6-inch circular base, and a temporary base 210 is, for example, a 14-inch, 20-inch, or 26-inch square base, but this disclosure is not limited thereto. In one embodiment, the adhesive layer 220 may cover the entire temporary base 210, but this disclosure is not limited to thereto.

Please refer to FIG. 1A and FIG. 1B, Next, the light-emitting elements 120 of the light-emitting elements supply substrates S1 are transferred to the adhesive layer 220 on the temporary base 210 to form the light-emitting elements supply substrate S2. In one embodiment, the light-emitting elements 120 and the first adhesive members 130 may be transferred to the adhesive layer 220 on the temporary base 210 at the same time, but this disclosure is not limited to thereto. For example, in one embodiment, laser lift-off (LLO) technology can be used to separate the first adhesive member 130 from the temporary base 110, thereby causing the first adhesive member 130 and the light-emitting elements 120 to be transferred on the adhesive layer 220 simultaneously, but this disclosure is not limited to thereto.

It should be noted that the light-emitting elements 120 of the light-emitting elements supply substrate S1 are sequentially transferred on the adhesive layer 220. Specifically, light-emitting elements 120 and the first adhesives 130 of the light-emitting elements supply substrate S1 may be transferred to a place of the adhesive layer 220 at the first point in time; after that, at a second time point following the first time point, light-emitting elements 120 of the next light-emitting elements supply substrate S1 are transferred to another place of the adhesive layer 220, thereby forming a light-emitting elements supply Substrate S2. FIG. 1A and FIG. 1B illustrate an example in which a plurality of light-emitting elements 120 of a light-emitting elements supply substrate S1 are transferred to one place of the adhesive layer 220.

Please refer to FIG. 1B, the light-emitting elements supply substrate S2 includes the temporary base 210 and the light-emitting elements 120, wherein the temporary base 210 has a first surface 212 and a second surface 214 facing each other, and the light-emitting elements 120 are disposed on the first surface 212 of the temporary base 210. In one embodiment, the light-emitting elements supply substrate S2 may optionally further include an adhesive layer 220, the adhesive layer 220 is disposed on the first surface 212 of the temporary base 210, and a plurality of light-emitting elements 120 is disposed on the adhesive layer 220. In one embodiment, the light-emitting elements supply substrate S2 may also optionally include of first adhesive members 130, each of the light-emitting elements 120 is located between a corresponding first adhesive member 130 and the adhesive layer 220, and the adhesive layer 220 is located between the light-emitting elements 120 and the temporary base 210. In one embodiment, an adhesive layer 220 may cover the entire temporary base 210, but this disclosure is not limited to thereto.

Please refer to FIG. 1C, next, a temporary substrate S3 is provided, wherein the temporary substrate S3 includes a temporary base 310 and an adhesive layer 320 disposed on the temporary base 310. In one embodiment, the adhesive layer 320 may cover the entire temporary base 310, but this disclosure is not limited to thereto.

Please refer to FIG. 1B and FIG. 1C, then, the temporary substrate S3 is placed on a stage t, and the first surface 212 of the temporary base 210 of the light-emitting elements supply substrate S2 faces the adhesive layer 320, so that light-emitting elements 120 disposed between the temporary base 210 of the light-emitting elements supply substrate S2 and the adhesive layer 320 of the temporary substrate S3. Next, the pressure head P is used to press down the second surface 214 of the temporary base 210 of the light-emitting elements supply substrate S2, so that the light-emitting elements 120 are connected to the adhesive layer 320, wherein there is a support member 600 between the pressure head P and a second surface 214 of the temporary base 210, and the pressure head P presses against the second surface 214 of the temporary base 210 through the support member 600.

The support member 600 is elastic. In one embodiment, the elastic recovery ratio of the support member 600 may be greater than or equal to 90%. The elastic recovery ratio can refer to [((A−A′))/A]×100%, wherein a vertical direction z is essentially perpendicular to the temporary base 310, and A is the thickness of the support member600 in the vertical direction z without pressure, A′ is the thickness of the support member 600 in the vertical direction z after the support member 600 is pressed by the pressure head P and the pressure exerted by the pressure head P is released for a period of time. In one embodiment, the thickness A of the support member 600 may fall in the range of 0.1 mm to 10 mm, but this disclosure is not limited thereto.

Please refer to FIG. 1C, in one embodiment, the temporary base 210 has a functional area 210a that overlaps light-emitting elements 120. The setting range of the support member 600 may fall within an allowable width W range of the functional area 210a being pushed outward or inward, the allowable width W is, for example, 5 mm, but this disclosure is not limited to thereto.

In one embodiment, the material of the support member 600 may include organic glue, tape, sponge, etc., but this disclosure is not limited thereto. In one embodiment, the support member 600 may be in the shape of a sheet overlapped with light-emitting elements 120. However, this disclosure is not limited to thereto. In other embodiments, the support member 600 may also be in other shapes, such as but not limited to: columnar, strip, etc.

Please refer to FIG. 1C and FIG. 1D, next, the temporary base 210 of the light-emitting elements supply substrate S2 and the light-emitting elements 120 are separated, so that the light-emitting elements 120 are transferred to the adhesive layer 320 of the temporary substrate S3. In one embodiment, the first adhesive members 130 may be transferred to the adhesive layer 320 of the temporary substrate S3 along with the light-emitting elements 120, the first adhesive members 130 are located between the light-emitting elements 120 and the adhesive layer 320, and the adhesive layer 320 is located between the first adhesive members 130 and the temporary base 310.

Referring to FIG. 1D, the light-emitting element array substrate 1 may include the temporary base 310, the adhesive layer 320 disposed on the temporary base 310, and the light-emitting elements 120 disposed on the adhesive layer 320. In one embodiment, the light-emitting element array substrate 1 may also optionally include first adhesive members 130 disposed between the light-emitting elements 120 and the adhesive layer 320; the adhesive layer 320 may include regions respectively overlapping with the first adhesive members 130, and the regions may be referred to as second adhesive members 322′; the first adhesive members 130 and the second adhesive members 322′ form adhesive structures SA1, wherein each of the adhesive structures SA1 includes a first adhesive members 130 and a second adhesive component 322′ stacked with each other.

In one embodiment, the adhesion structure SA1 and the electrodes 124 and 125 of the light-emitting element 120 are disposed on the same side of the active layer 123 of the light-emitting element 120. In one embodiment, the adhesion structures SA1 are disposed between the light-emitting elements 120 and the temporary base 310. In one embodiment, the second adhesive members 322′ of the adhesive structures SA1 may be regions of the adhesive layer 320 that respectively overlap with the first adhesive members 130, and the second adhesive members 322′ are connected directly.

Referring to FIG. 1D and FIG. 1E, then, the adhesive layer 320 on the temporary base 310 may be patterned to form second adhesive members 322 separated from each other, wherein the first adhesive members 130 are located between the light-emitting elements 120 and the second adhesive members 322, and the second adhesive members 322 are located between the first adhesive members 130 and the temporary base 310. For example, in one embodiment, light-emitting elements 120 may be used as hard masks, and the adhesive layer 320 may be subjected to a dry etching process to form the second adhesive members 322 separated from each other.

Referring to FIG. 1E, the light-emitting element array substrate 2 includes the temporary base 310, the light-emitting elements 120 disposed on the temporary base 310, and the adhesion structures SA2 respectively located on the light-emitting elements 120, wherein each of the adhesion structures SA2 includes a first adhesive member 130 and a second adhesive member 322 stacked with each other. In one embodiment, the adhesion structures SA2 are separated from each other.

Referring to FIG. 1E and FIG. 1G, then, the light-emitting elements 120 and the adhesive structures SA2 on the temporary base 310 are selectively transferred to an adhesive layer 420 on the temporary base 410 to form another light-emitting element array substrate 3. For example, in one embodiment, laser lift-off (LLO) technology may be used to separate the adhesive structure SA2 from the temporary base 310, so that the adhesive structure SA2 and the light-emitting elements 120 are transferred to the adhesive layer 420 on the temporary base 410 to form the light-emitting element array substrate 3.

The arrangement of the light-emitting elements 120 of the light-emitting element array substrate 2 is different from the arrangement of the light-emitting elements 120 of another light-emitting element array substrate 3. The arrangement of the light-emitting elements 120 of another light-emitting element array substrate 3 is depends on the location of the pads 520 (shown in FIG. 1H) of the driving backplane 510 (shown in FIG. 1H) of the display device DP (shown in FIG. 1H).

It should be noted that the light-emitting elements 120 shown in FIG. 1E are light-emitting elements 120R, 120G or 120B used to emit the same color. The methods shown in FIGS. 1A to 1E may be used repeatedly to form a variety of light-emitting element array substrates 2, wherein each of the light-emitting element array substrates 2 includes light-emitting elements 120R, 120G or 120B for emitting light beams with a single color. After repeatedly using the method shown in FIGS. 1A to 1E to form a variety of light-emitting element array substrates 2 for emitting light beams of multiple colors, then, light-emitting elements 120R of one of the light-emitting element array substrates 3, light-emitting elements 120G of the other of the light-emitting element array substrates 2, and light-emitting elements 120B of yet another of the light-emitting element array substrates 2 are respectively selectively transferred to the adhesive layer 420 on the temporary base 410 to form a light-emitting element array substrate 3 including a variety of light-emitting elements 120R, 120G, and 120B, wherein the light-emitting element array substrate 3 has light-emitting elements120R, 120G, 120B used to emit light beams with different colors. For example, in one embodiment, the light-emitting elements 120R, 120G, and 120B of the light-emitting element array substrate 3 may be used to emit red light, green light, and blue light, but this disclosure is not limited to thereto.

Referring to FIG. 1F, the light-emitting element array substrate 3 includes a temporary base 410, light-emitting elements 120R, 120G, and 120B disposed on the temporary base 410, and adhesive structures SA2 respectively located on the light-emitting elements 120R, 120G, and 120B, wherein each of the adhesive structure SA2 includes a first adhesive member 130 and a second adhesive member 322 stacked with each other. The light-emitting elements 120R, 120G, and 120B are disposed between the adhesion structures SA2 and the temporary base 410. The light-emitting element array substrate 3 further includes an adhesive layer 420 disposed on the temporary base 410, wherein the light-emitting elements 120R, 120G, and 120B are disposed on the adhesive layer 420, the light-emitting elements 120R, 120G, and 120B are located between the adhesion structures SA2 and the adhesive layer 420, and the adhesive layer 420 is located between the light-emitting elements 120R, 120G, 120B and the temporary base 410.

Referring to FIG. 1F and FIG. 1G, then, the adhesive structures SA2 on the light-emitting elements 120R, 120G, and 120B are removed to expose the electrodes 124 and 125 of the light-emitting elements 120R, 120G, and 120B. For example, in one embodiment, a dry etching process can be used to remove the adhesion structures SA2 on the light-emitting elements 120R, 120G, and 120B.

Referring to FIG. 1G and FIG. 1H, next, the light-emitting elements 120R, 120G, and 120B on the temporary base 410 are transferred to the driving backplane 510, and the electrodes 124 and 125 of the light-emitting elements 120R, 120G, and 120B are electrically connected to pads 520 of the driving backplane 510 to form a display device DP. The display device DP includes the driving backplane 510 and the light-emitting elements 120R, 120G, 120B, wherein the pads 520 of the driving backplane 510 are electrically connected to the electrodes 124, 125 of the light-emitting elements 120R, 120G, 120B. For example, in one embodiment, a laser bonding process may be used to electrically connect the electrodes 124 and 125 of the light-emitting elements 120R, 120G, and 120B to the pads 520 of the driving backplane 510.

As mentioned above, light-emitting elements 120 are first transferred from multiple small-area temporary bases 110 to a large-area temporary base 210, and then simultaneously transferred from the same temporary base 210 to a temporary base 310, and then selectively transferred from the same temporary base 310 to a temporary base410. The light-emitting elements 120R, 120G or 120B that are transferred onto the temporary base 310 and used to emit light beams of the same color are from the same temporary base 310 with a large area. Therefore, in the process of transferring the light-emitting elements 120R, 120G or 120B used to emit light beams of the same color, the temporary base 410 may be aligned with the temporary base 310 of the same large block, without the need to align with the temporary base 310 of multiple small blocks. Thereby, the overall offset of the multiple light-emitting elements 120R, 120G, and 120B on the temporary base 410 can be greatly reduced, thereby improving the bonding yield of the light-emitting elements 120R, 120G, and 120B and the driving backplane 510. In addition, the speed of transposition can also be improved.

In addition, it is worth noting that, as shown in FIG. 1C and FIG. 1D, through the buffering effect of the support member 600, the problem of bonding mura of the light-emitting element array substrate 1 caused by the flatness and/or parallelism of the pressure head P/platform T can be improved, the film thickness uniformity of the adhesive layer 320 can also be improved. Specifically, without using support member 600 as a buffer layer, the film thickness uniformity of the adhesive layer 320 is ˜10%, but after using support member 600 as a buffer layer, the film thickness uniformity of an adhesive layer 320 can be improved to ˜3.3%.

It must be noted here that the following embodiments follow the component numbers and part of the content of the previous embodiments, wherein the same numbers are used to represent the same or similar elements, and descriptions of the same technical content are omitted. For descriptions of omitted parts, please refer to the foregoing embodiments and will not be repeated in the following embodiments.

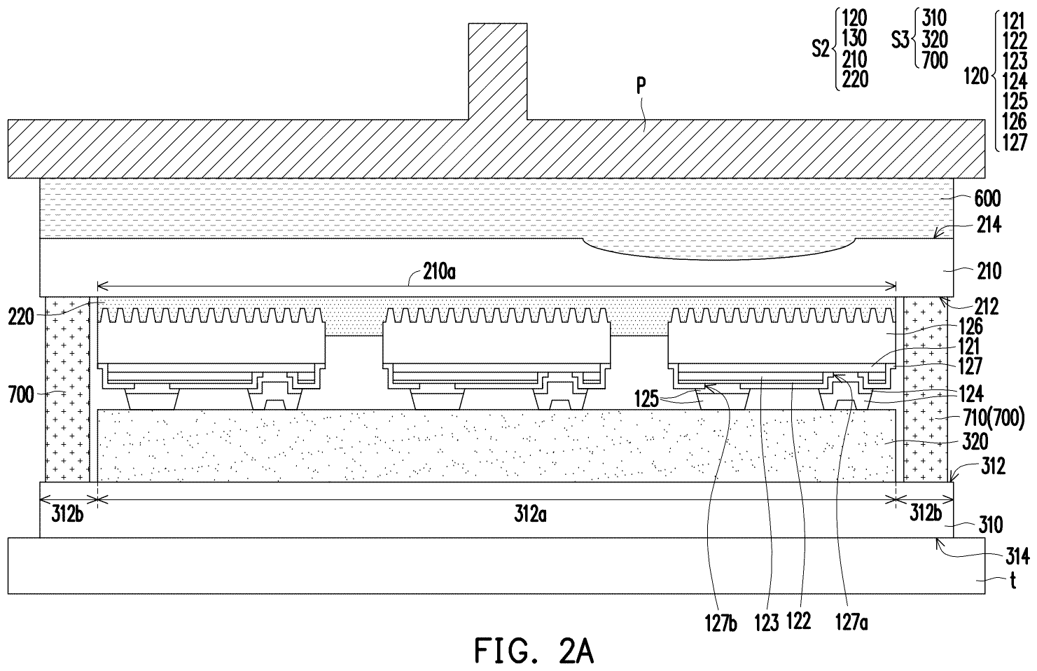

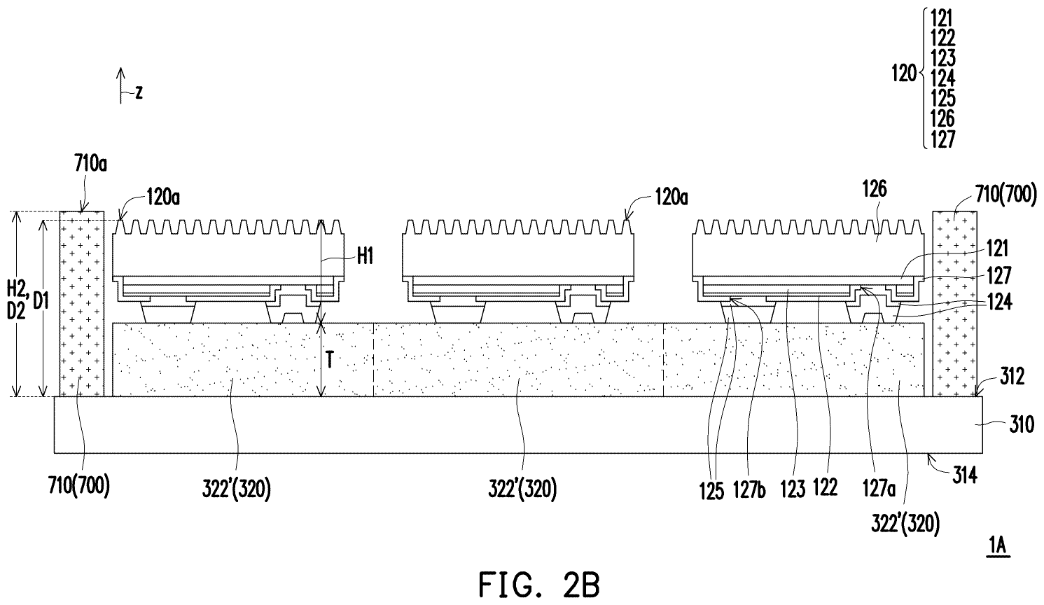

FIG. 2A to FIG. 2B are schematic cross-sectional views of a part of the manufacturing process of a display device according to another embodiment of the present disclosure. Part of the manufacturing process in FIG. 2A to FIG. 2B is similar to the aforementioned part of the manufacturing process in FIG. 1C to FIG. 1D. The differences between the two are: in the embodiment of FIG. 2A to FIG. 2B, when the pressure head P is used to press down the a second surface 214 of the temporary base 210 of the light-emitting elements supply substrate S2, in addition to the support member 600 provided between the second surface 214 of the temporary base 210 and the pressure head P, a support member 700 is also provided between the temporary base 210 of the light-emitting elements supply substrate S2 and the temporary base 310 of the temporary substrate S3. In addition, in the embodiment of FIGS. 2A to 2B, the first adhesive member 130 of the embodiment of FIGS. 1C to 1D is omitted.

Referring to FIG. 2A, specifically, in one embodiment, the temporary base 310 has a first surface 312 and a second surface 314 opposite to each other. The first surface 312 of the temporary base 310 has a functional area 312a and a non-functional area 312b, the functional area 312a and the light-emitting elements 120 are overlapped, the non-functional area 312b is located outside the functional area 312a and is staggered from the light-emitting elements 120, and the support member 700 may include a first support member 710 disposed on the non-functional area 312b of a first surface 312 of the temporary base 310. When the pressure head P is used to press down the second surface 214 of the temporary base 210 of the light-emitting elements supply substrate S2, the support member 700 can also play a buffering role to further improve the film thickness uniformity of the adhesive layer 320. For example, in one embodiment, when the support member 600 and the support member 700 are used as buffer layers, the film thickness uniformity of the adhesive layer 320 can be further improved to ˜2%. In addition, compared with the embodiment of FIG. 1C and FIG. 1D, in the embodiment of FIG. 2A to FIG. 2B, the position offset of the light-emitting elements 120 located near the edge of the functional area 312a can also be significantly reduced.

Referring to FIG. 2A and FIG. 2B, after separating the temporary base 210 of the light-emitting elements supply substrate S2 and the light-emitting elements 120, the light-emitting elements 120 are transferred to the adhesive layer 320. At this time, the light-emitting element array substrate 1A is formed.

Referring to FIG. 2B, the light-emitting element array substrate 1A includes a temporary base 310, an adhesive layer 320, light-emitting elements 120 and at least one support member 700. The temporary base 310 has a first surface 312 and a second surface 314 opposite to each other. The adhesive layer 320 is disposed on the first surface 312 of the temporary base 310. The light-emitting elements 120 are disposed on the adhesive layer 320, wherein the adhesive layer 320 is located between the light-emitting elements 120 and the temporary base 310. The at least one support member 700 is disposed on at least one of the first surface 312 and the second surface 314 of the temporary base 310.

In one embodiment, the at least one support member 700 includes a first support member 710 disposed on a non-functional area 312b of a first surface 312 of the temporary base 310. In one embodiment, the first support member 710 may be fabricated on the first surface 312 of the temporary base 310 using a yellow light process, but this disclosure is not limited to thereto. In one embodiment, the first support member 710 may be in the form of multiple sheets disposed on the non-functional area 312b, but this disclosure is not limited to thereto.

In one embodiment, a vertical direction z is substantially perpendicular to the temporary base 310, a surface 120a of a light-emitting element 120 facing away from the temporary base 310 and a first surface 312 of the temporary base 310 have a first distance D1 in the vertical direction z, and the surface 710a of the first support member 710 facing away from the temporary base 310 and a first surface 312 of the temporary base 310 have a second distance D2 in the vertical direction z, and D1×90%≤D2≤D1×110%.

In one embodiment, the vertical direction z is substantially perpendicular to the temporary base 310, a light-emitting element 120 has a height H1 in the vertical direction z, an adhesive layer 320 has a thickness T in the vertical direction z, and the first support member 710 has a height H2, and (H1+T)×90%≤H2≤(H1+T)×110%.

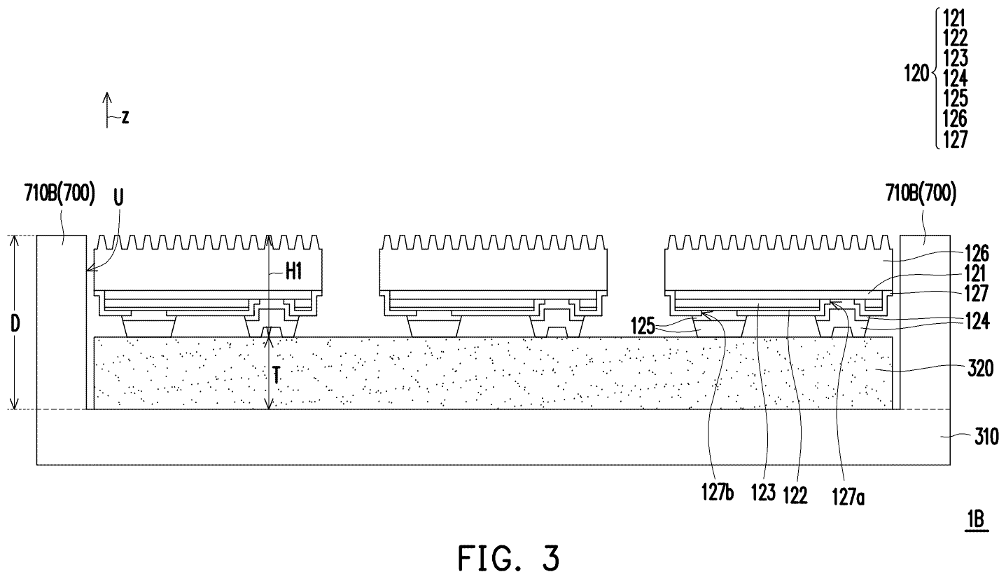

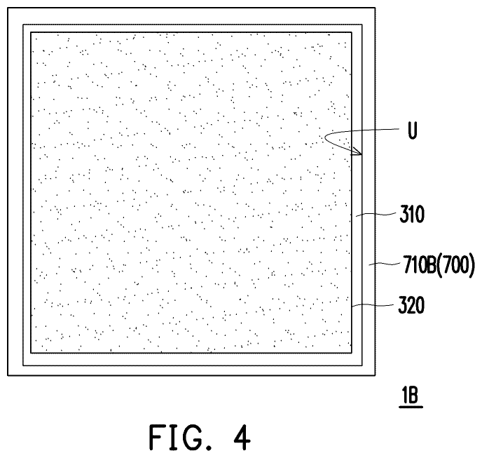

FIG. 3 is a schematic cross-sectional view of a light-emitting element array substrate according to another embodiment of the present disclosure. FIG. 4 is a schematic top view of a light-emitting element array substrate according to another embodiment of the present disclosure. FIG. 4 omits the light-emitting elements 120 of FIG. 3.

The light-emitting element array substrate 1B of FIG. 3 and FIG. 4 is similar to the light-emitting element array substrate 1A of FIG. 2B. The difference between the two is that the first support members 710 and 710B are different. Specifically, in the embodiments of FIGS. 3 and 4, the first support member 710B and the temporary base 310 are integrally formed. The first support member 710B and temporary base 310 define groove U, and an adhesive layer 320 and light-emitting elements 120 are disposed in groove U.

Referring to FIG. 3, in one embodiment, the groove U has a depth D in the vertical direction z, a light-emitting element 120 has a height H1 in the vertical direction z, an adhesive layer 320 has a thickness T in the vertical direction z, and (H1+T)×90%≤D≤(H1+T)×110%.

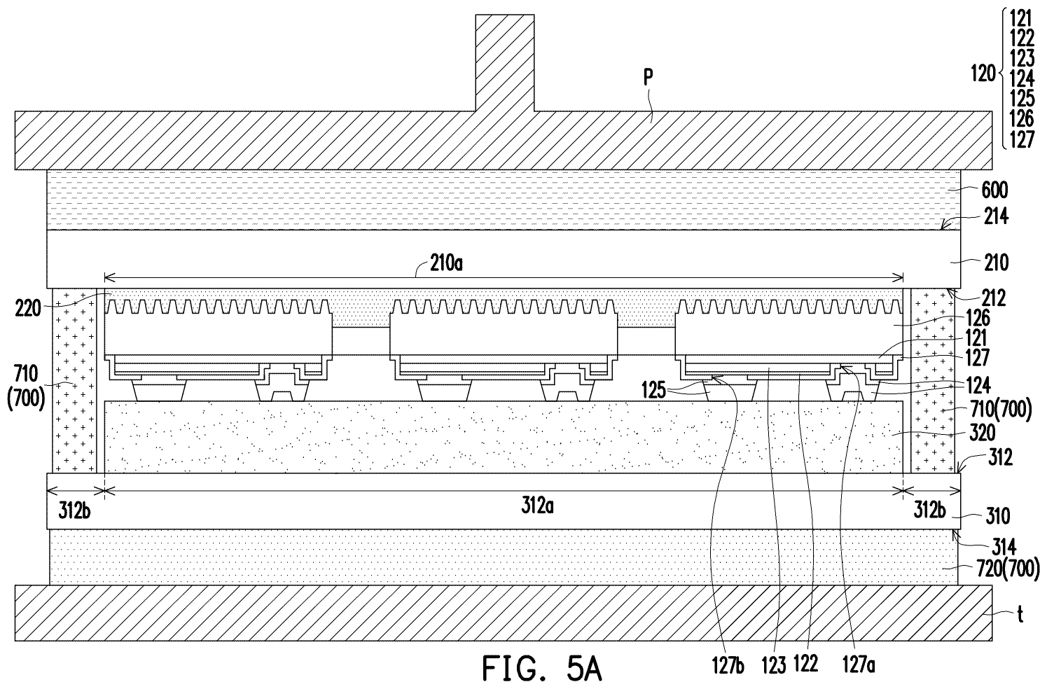

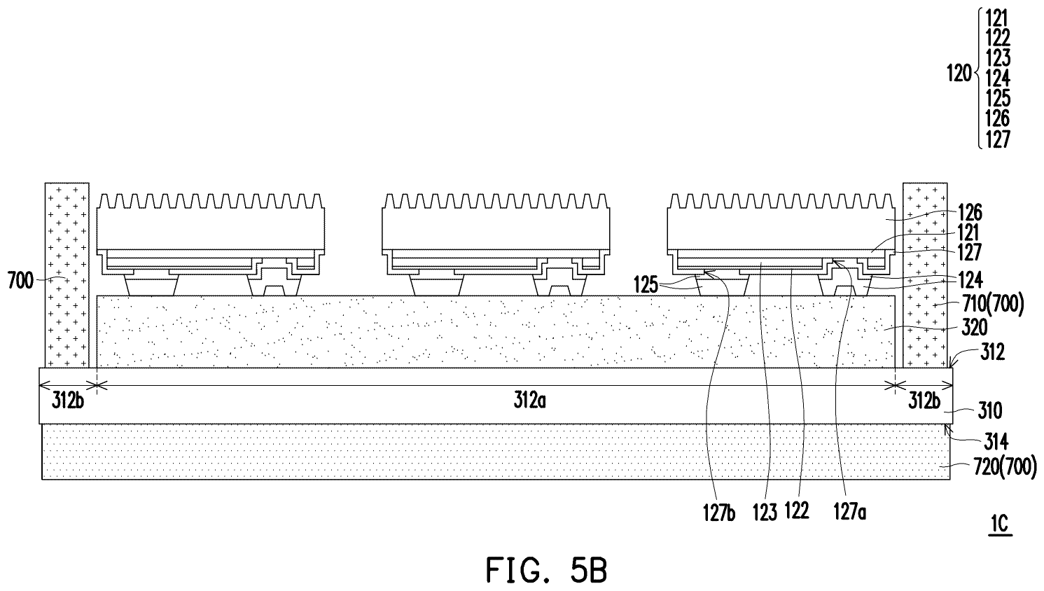

FIG. 5A to FIG. 5B are schematic cross-sectional views of a part of the manufacturing process of a display device according to another embodiment of the present disclosure. A part of the manufacturing process in FIG. 5A to FIG. 5B is similar to the part of the manufacturing process in FIG. 2A to FIG. 2B mentioned above. The difference between the two is: in the embodiment of FIGS. 5A to 5B, when the pressure head P is used to press down a second surface 214 of the temporary base 210 of the light-emitting elements supply substrate S2, in addition to the support member 600 being provided between the temporary base 210 of the light-emitting elements supply substrate S2 and the pressure head P, and the support member 700 being provided between the temporary base 210 of the light-emitting elements supply substrate S2 and the temporary base 310 of the temporary substrate S3, there is also a support member700 between the stage t and the temporary base 310.

Referring to FIG. 5A, when the pressure head P is used to press down a second surface 214 of the temporary base 210 of the light-emitting elements supply substrate S2, the support member 700 disposed between the stage t and the temporary base 310 can also play a buffering role, and the film thickness uniformity of an adhesive layer 320 is further improved. Referring to FIG. 5A and FIG. 5B, after separating the temporary base 210 of the light-emitting elements supply substrate S2 and the light-emitting elements 120, the light-emitting elements 120 are transferred to an adhesive layer 320. At this time, the light-emitting element array substrate 1C is formed.

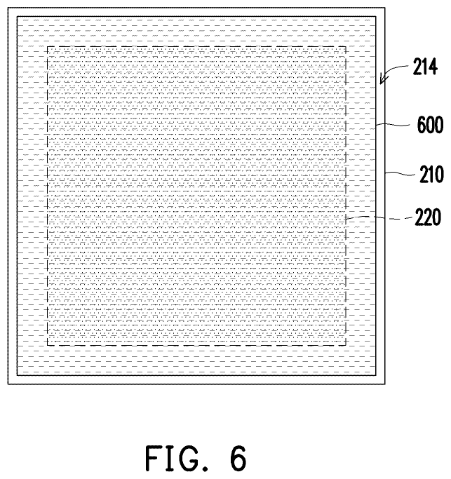

FIG. 6 is a top view and a perspective view of a temporary base, an adhesive layer and a support member of another embodiment of the disclosure. Referring to FIGS. 5A and 6, in one embodiment, the support member 600 may be disposed on a second surface 214 of the temporary base 210 and overlap with an adhesive layer 220. In one embodiment, the support member 600 may be selectively in a sheet shape and cover the entire surface of a second surface 214 of the temporary base 210.

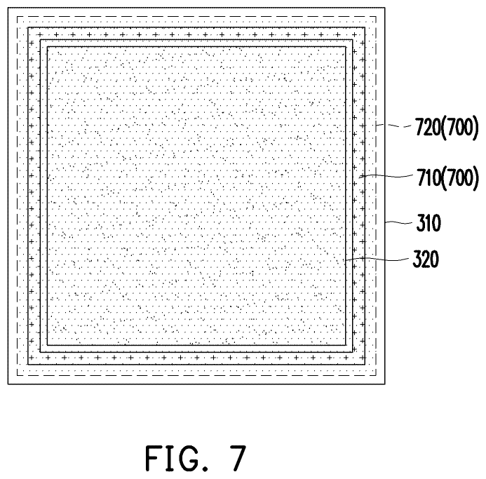

FIG. 7 is a top view and a perspective view of an adhesive layer, a temporary base, a first support member and a second support member of a light-emitting element array substrate according to yet another embodiment of the present disclosure. Referring to FIG. 5B and FIG. 7, the light-emitting element array substrate 1C includes a temporary base 310, an adhesive layer 320, a plurality of light-emitting elements 120 and at least one support member 700. The temporary base 310 has a first surface 312 and a second surface 314 opposite to each other. An adhesive layer 320 is disposed on the first surface 312 of the temporary base 310. The light-emitting elements 120 are disposed on the adhesive layer 320, wherein the adhesive layer 320 is located between the light-emitting elements 120 and the temporary base 310. At least one support member 700 is disposed on at least one of a first surface 312 and a second surface 314 of the temporary base 310.

Different from the light-emitting element array substrate 1B of FIG. 2B, at least one support member 700 of the light-emitting element array substrate 1C includes not only the first support member 710 disposed on a first surface 312 of the temporary base 310, but also includes a second support member 720 on a second surface 314 of the temporary base 310. In one embodiment, the second support member 720 may selectively cover a second surface 314 of the temporary base 310 and overlap an adhesive layer 320 and the first support member 710.

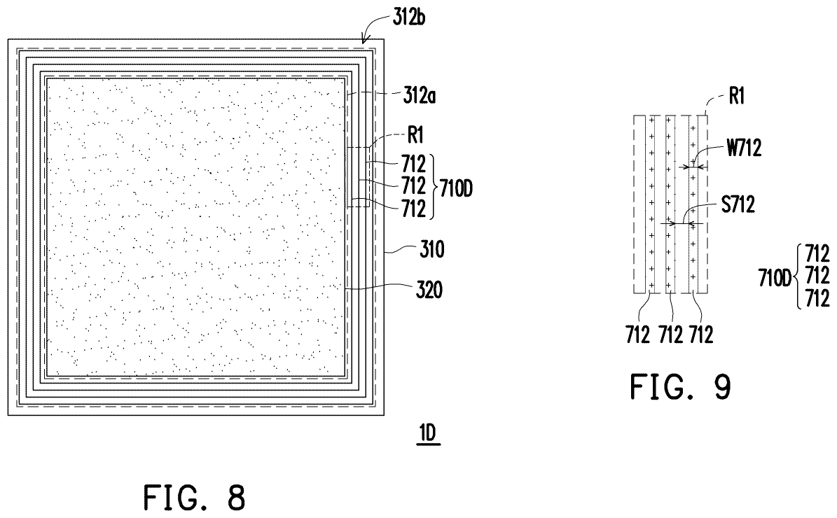

FIG. 8 is a top view and a perspective view of a temporary base, an adhesive layer and a first support member of a light-emitting element array substrate according to an embodiment of this disclosure. FIG. 9 is a partially enlarged schematic diagram of the first support member of an embodiment of the disclosure. FIG. 9 corresponds to the local region R1 of FIG. 8.

Referring to FIGS. 8 and 9, in one embodiment, the first support member 710D may include a plurality of strip portions 712 that are separated from each other. In one embodiment, the width W712 of a strip portion 712 may fall in the range of 3 μm to 10 μm. In one embodiment, the gap width S712 of two adjacent strip portions 712 may be approximately 3 μm. In one embodiment, the ratio of the area of the strip portion 712 of the first support member 710D to the area of the non-functional area 312b may fall within the range of 50% to 97%. In one embodiment, the area of the non-functional area 312b may refer to the area of the temporary base 310 that is not occupied by an adhesive layer 320.

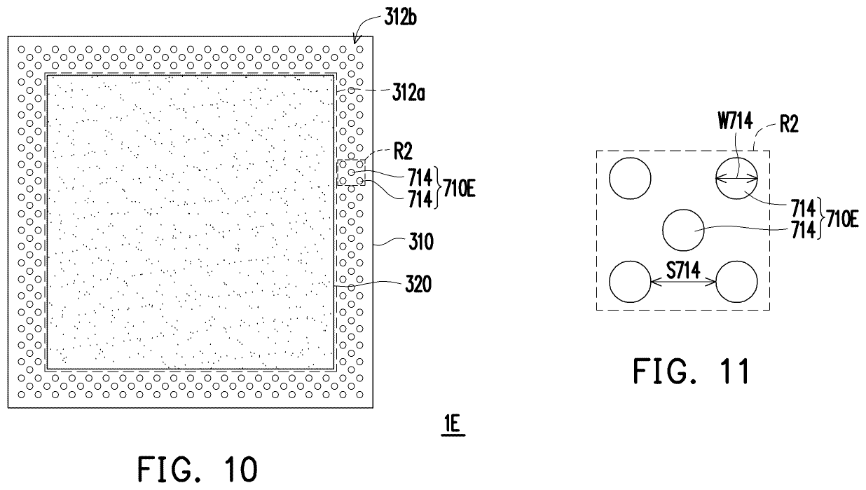

FIG. 10 is a top view and a perspective view of a temporary base, an adhesive layer and a first support member of a light-emitting element array substrate according to another embodiment of this disclosure. FIG. 11 is a partially enlarged schematic diagram of the first support member of another embodiment of the disclosure. FIG. 11 corresponds to the local region R2 of FIG. 10.

Referring to FIGS. 10 and 11, in one embodiment, the first support member 710E may include columnar portions 714 that are separated from each other. In one embodiment, the width W714 of a column portion 714 may fall in the range of 3 μm to 10 μm. In one embodiment, the gap width S714 of two adjacent column portions 714 may be approximately 3 μm. In one embodiment, the ratio of the areas of the column portions 714 of the first support member 710E to the area of the non-functional area 312b may fall in the range of 50%˜ 97%.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A light-emitting element array substrate comprising:
a temporary base having a first surface and a second surface opposite to each other;
an adhesive layer disposed on the first surface of the temporary base;
a plurality of light-emitting elements disposed on the adhesive layer, wherein the adhesive layer is located between the light-emitting elements and the temporary base; and
at least one support member disposed on at least one of the first surface and the second surface of the temporary base.

2. The light-emitting element array substrate according to claim 1, wherein an elastic recovery ratio of the at least one support member is greater than or equal to 90%.

3. The light-emitting element array substrate according to claim 1, wherein the first surface of the temporary base has a functional area and a non-functional area, the functional area overlaps the light-emitting elements, and the non-functional area is located outside the functional area and staggered with the light-emitting elements, the at least one support member comprises:
a first support member, located on the non-functional area of the first surface of the temporary base.

4. The light-emitting element array substrate according to claim 3, wherein the at least one support member further comprises:
a second support member, disposed on the second surface of the temporary base.

5. The light-emitting element array substrate according to claim 3, wherein a vertical direction is substantially perpendicular to the temporary base, a surface of a light-emitting element of the light-emitting elements facing away from the temporary base and the first surface of the temporary base have a first distance D1 in the vertical direction, a surface of the first support member facing away from the temporary base and the first surface of the temporary base have a second distance D2 in the vertical direction, and D1×90%≤D2≤D1×110%.

6. The light-emitting element array substrate according to claim 3, wherein a vertical direction is substantially perpendicular to the temporary base, a light-emitting element of the light-emitting elements has a height H1 in the vertical direction, the adhesive layer has a thickness T in the vertical direction, and the first support member has a height H2 in the vertical direction, and (H1+T)×90%≤H2≤(H1+T)×110%.

7. The light-emitting element array substrate according to claim 3, wherein the first support member is integrated with the temporary base.

8. The light-emitting element array substrate according to claim 7, wherein the first support member and the temporary base define a groove, and the adhesive layer and the light-emitting elements are disposed in the groove.

9. The light-emitting element array substrate according to claim 8, wherein a vertical direction is substantially perpendicular to the temporary base, the groove has a depth D in the vertical direction, a light-emitting element of the light-emitting elements has a height H1 in the vertical direction, and the adhesive layer has a thickness T in the vertical direction, and (H1+T)×90%≤D≤(H1+T)×110%.

10. The light-emitting element array substrate according to claim 8, wherein the at least one support member comprises column portions separated from each other or strip portions separated from each other.

11. A manufacturing method of a light-emitting element array substrate comprising:
providing a light-emitting elements supply substrate, wherein the light-emitting elements supply substrate comprises a temporary base and light-emitting elements, the temporary base of the light-emitting elements supply substrate has a first surface and a second surface opposites to each other, and the light-emitting elements are disposed on the first surface of the temporary base of the light-emitting elements supply substrate;
providing a temporary substrate, wherein the temporary substrate comprises a temporary base and an adhesive layer disposed on the temporary base;
making the first surface of the temporary base of the light-emitting elements supply substrate face the adhesive layer, so that the light-emitting elements are disposed between the temporary base of the light-emitting elements supply substrate and the adhesive layer of the temporary substrate;
using a pressure head to press down the second surface of the temporary base of the light-emitting elements supply substrate, so that the light-emitting elements are connected to the adhesive layer of the temporary substrate, wherein a support member is provided between the pressure head and the second surface of the temporary base of the light-emitting elements supply substrate, and the pressure head presses against the second surface of the temporary base of the light-emitting elements supply substrate through the support member; and
separating the temporary base of the light-emitting elements supply substrate and the light-emitting elements so that the light-emitting elements are transferred to the adhesive layer of the temporary substrate.

12. The manufacturing method of the light-emitting element array substrate according to claim 11, wherein an elastic recovery ratio of the support member is greater than or equal to 90%.
